(19) United States
(12) Patent Application Publication
(10) Pub. No.: US 2008/0187683 A1
(43) Pub. Date: Aug. 7, 2008

(54) RESONANT INFRARED LASER-ASSISTED NANOPARTICLE TRANSFER AND APPLICATIONS OF SAME

(75) Inventors: Richard F. HAGLUND, Brentwood, TN (US); Erik M. Herz, Ithaca, NY (US); Michael R. Papantonakis, Washington, DC (US); Duane Leslie Simonson, Alexandria, VA (US); Ulrich B. Wiesner, Ithaca, NY (US)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignees: Vanderbilt University, Nashville, TN (US); Naval Research Laboratory, Washington, DC (US); Cornell Research Foundation, Inc., Ithaca, NY (US)

(21) Appl. No.: 11/775,308

(22) Filed: Jul. 10, 2007

Related U.S. Application Data
(60) Provisional application No. 60/819,598, filed on Jul. 10, 2006.

(51) Int. Cl. C23C 14/28; C23C 16/44

(52) U.S. Cl. 427/596; 118/722

(57) ABSTRACT

A method for depositing particles onto a substrate. In one embodiment, the method providing a plurality of particles in a solvent or a matrix of solvents to form a solution; freezing the solution to form a target having a surface; irradiating the target with a light of a wavelength in the infrared region which is resonant with a vibrational mode of the target so as to vaporize the particles in the target without decomposing the particles; and depositing the vaporized particles onto the substrate at a deposition rate to form a film of particles thereon, where the substrate is positioned such that the substrate and the target define a distance therebetween.

### CROSS-REFERENCE TO RELATED PATENT APPLICATION

This application claims the benefit, pursuant to 35 U.S.C. § 19(e), of U.S. provisional patent application Ser. No. 60/819,598, filed Jul. 10, 2006, entitled “RESONANT INFRARED LASER-ASSISTED NANOPARTICLE TRANSFER AND APPLICATIONS OF SAME,” by Richard F. Haglund, Jr., Erik M. Herz, Michael R. Papantonakis, Duane Leslie Simonsen, and Ulrich B. Wiesner, which is incorporated herein by reference in its entirety.

This application is related to a co-pending U.S. patent application Ser. No. 11/337,301, filed Jan. 23, 2006, entitled “METHODS AND APPARATUS FOR TRANSFERRING A MATERIAL ONTO A SUBSTRATE USING A RESONANT INFRARED PULSED LASER,” by Richard F. Haglund, Jr., Nicole L. Dygert, and Kenneth E. Schriver. The identified co-pending application is a continuation-in-part of U.S. patent application Ser. No. 10/059,978, filed Jan. 29, 2002, now issued as U.S. Pat. No. 6,998,156, entitled “DEPOSITION OF THIN FILMS USING AN INFRARED LASER,” by Daniel Bubb, James Horwitz, John Callahan, Richard Haglund, Jr. and Michael Papantonakis, and also claims the benefit, pursuant to 35 U.S.C. § 119(e), of U.S. provisional patent application Ser. No. 60/714,819, filed Sep. 7, 2005, entitled “A RESONANT INFRARED PULSED LASER SYSTEM FOR TRANSFERRING A MATERIAL ONTO A SUBSTRATE AND APPLICATIONS OF SAME,” by Richard F. Haglund, Jr., Nicole L. Dygert, and Kenneth E. Schriver, the contents of which are incorporated herein in their entireties by reference, respectively.

Some references, which may include patents, patent applications and various publications, are cited and discussed in the description of this invention. The citation and/or discussion of such references is provided merely to clarify the description of the present invention and is not an admission that any such reference is “prior art” to the invention described herein. All references cited and discussed in this specification are incorporated herein by reference in their entireties and to the same extent as if each reference was individually incorporated by reference. In terms of notation, hereinafter, “[n]” represents the nth reference cited in the reference list. For example, [10] represents the 10th reference cited in the reference list, namely, “Mode-specific effects in resonant ablation and deposition of polystyrene,” D. M. Bubb, S. L. Johnson, Jr., R. J. Belmont, K. E. Schriver, R. F. Haglund, Jr., C. Antonacci and L. S. Yeung, Applied Physics A: Materials and Processing 83, 147-151 (2006).

### STATEMENT OF FEDERALLY-SPONSORED RESEARCH

The present invention was made with Government support awarded by the Department of Defense Medical Free-Electron Laser Program under Contract No. F49620-01-1-0429 and Naval Research Laboratory, Procurement Orders N00173-05-P-0059 and N00173-05-P-0922. The United States Government may have certain rights to this invention pursuant to these grants.

### FIELD OF THE INVENTION

The present invention generally relates to laser vaporization deposition and in particular to methods and apparatus of infrared laser vaporization deposition of thin films of one or more types of particles including nanoparticles onto a substrate.

### BACKGROUND OF THE INVENTION

Infrared pulsed laser deposition (PLD) was first reported in 1960's but did not emerge as a thin film coating technology at that time for a number of reasons. These include the slow repetition rate of the available lasers, and the lack of commercially available high power lasers. At that time, infrared PLD used infrared laser light of 1.06 μm that was not resonant with any single photon absorption band of the material being deposited. Although PLD developed through the years it was not until late 1980's that ultraviolet PLD became popular with the discovery of complex superconducting ceramics and the commercial availability of high energy, high repetition rate lasers. Ultraviolet PLD is now a common laboratory technique used for the production of a broad range of thin film materials.

Resonant Infrared Pulsed Laser Deposition (RIR-PLD) has been used to successfully deposit a wide variety of polymers, functionalized polymers, oligomers and biopolymers without physical or chemical modifications to those materials. However, there are no extant reports of the transfer of micro- or nanoparticles using this technique.

Matrix-Assisted Pulsed Laser Evaporation (MAPLE), and its close cousin MAPLE-DW (Direct Write) with ultraviolet lasers have been used to deposit polymers and particulate materials on substrates, but both techniques are disadvantaged by low growth rates and lack of general applicability to organic materials. Furthermore, MAPLE-DW does not work for nanoparticles because of focal spot diameter.

Dip Coating and Spin Coating can be used to generate continuous films of polymeric materials and particle suspensions. However, it is difficult to consistently obtain uniform films with these techniques, partially because the evaporation dynamics in the evaporating solvent tend favors segregation of the suspended nanoparticles in domains along the margins of the solvent/surface interface.

Pipetting or Inkjetting provides better control over material delivery either in defined patterns or to specific locations on a substrate, but suffer from the same difficulties with regard to film uniformity as those listed above for dip coating and spin coating.

Over the years, certain technologies related to the technologies discussed above have been patented as shown by the following partial list of U.S. patents in the field:
U.S. Pat. No. 6,998,156, issued Feb. 14, 2006, which relates to the deposition of thin films using infrared laser irradiation where an organic polymer is transferred in a controlled manner to a substrate without significant physical or chemical degradation. At least two of the inventors of this patent are also co-inventors of the present invention.
U.S. Pat. No. 6,825,045, issued Nov. 30, 2004, which relates to a “System and Methods of Infrared Matrix-Assisted Laser Desorption/Ionization Mass Spectrometry in Polyacrylamide Gels.” This invention provides resonant infrared laser ablation of a volume of a polyacrylamide gel or other matrix containing proteins that are ionized in the ablation event, for subsequent analysis by mass spectrometry. At least two of the inventors of this patent are also co-inventors of the present invention.
U.S. Pat. No. 6,025,036, issued Feb. 15, 2000, which is understood to describe the transfer of polymeric vapor by matrix-assisted pulsed laser evaporation (MAPLE) whereby polymeric material is originally present as a minor species of a solid target. The polymeric vapor then condenses on a substrate while the major species of the target is pumped away by a vacuum system. However, this patent discloses the use of ultraviolet lasers, which is not generally suitable for organic materials, and does not describe the necessity of using infrared irradiation for organic materials in general.
U.S. Pat. No. 6,660,343, issued Dec. 9, 2006, which is understood to describe the assembly of composite and/or layered materials (including nanoparticles) using MAPLE, specifically the transfer of carbonaceous or metallic materials for the production of chemiresistors. The technology also suffers from the same limitations with regard to using ultraviolet radiation as described for the preceding patent.

Therefore, a heretofore unaddressed need still exists in the art to address the aforementioned deficiencies and inadequacies.

### SUMMARY OF THE INVENTION

The present invention, in one aspect, relates to a method for depositing particles onto a substrate. The particles include microparticles or nanoparticles having a dimension in the range of about 1 nm to 500 μm. The nanoparticles can be nanotubes, nanofibers, nanowires, quantum dots, or the like. The particles include functionalized particles, such as conductive particles, semiconductive particles, insulative particles, magnetic particles, therapeutic agents, or the like. The functionalized particles may have one or more organic ligands.

In one embodiment, the method includes the steps of providing a plurality of particles in a solvent or a matrix of solvents to form a solution; freezing the solution to form a target having a surface; irradiating the target with a light of a wavelength in the infrared region which is resonant with a vibrational mode of the target so as to vaporize the particles in the target without decomposing the particles; and depositing the vaporized particles onto the substrate at a deposition rate to form a film of particles thereon. The film may be formed in a pattern. In one embodiment, the thickness of the film of particles deposited on the substrate is in the range of about 1 nm to 500 μm. The substrate is positioned such that the substrate and the target define a distance therebetween. The distance between the target and the substrate is in the range of about 1 to 20 cm, which allows the ablated solvent or solvents to be moved away without reaching the substrate.

In one embodiment, the solvent or matrix of solvents comprises water. The particles in the solution are in the range of about 0.1% to 40% by weight.

In one embodiment, the providing step further comprises the step of adding a polymeric material into the solution.

In one embodiment, the irradiating step includes the step of directing the light at the surface of the target along a direction that defines an angle, α, with a normal direction of the surface of the target, where the angle α is greater than 0. Furthermore, the irradiating step includes the step of rastering the light onto the surface of the target. In one embodiment, the target is positioned in a target holder that is rotated during the rastering step to allow the light to evenly cover the surface of the target. Moreover, the irradiating step includes the step of regulating the intensity of the light so that the average fluence of the light is between a first value and a second value that is greater than the first value, where the first value is corresponding to the ablation threshold for the target.

The vibrational mode of the target is selectable from an absorption spectrum of the target, and is selected such that there is substantially no electronic excitation in the target caused by irradiating the target with the light. The vibrational mode of the target is resonant with at least one vibrational mode of the solvent or matrix of solvents in a liquid form or a solid form. The vibrational mode of the target, in one embodiment, is in the infrared region of about 0.1-10,000.0 μm.

In one embodiment, the light of a wavelength in the infrared region which is resonant with a vibrational mode of the target comprises a laser beam that is generated by a laser. The laser comprises a tunable laser. The laser beam is provided in the form of one or more pulses having a pulse duration of about 100 fs to 5 ms at a pulse repetition frequency in the range of about 1 Hz to 3 GHz. In one embodiment, the deposition rate of particles on the substrate is in the range of about 0.001 to 300 ng/cm²/pulse. In one embodiment, the laser may operate in a continuous wave mode.

Additionally, the method also includes the steps of subjecting the target and the substrate to an environment selected from the group consisting of sub-atmospheric, atmospheric and above atmospheric pressure and locating the target and the substrate in the vicinity of each other so that the vaporized particles from the target can be deposited on the substrate by a movement of the vaporized particles caused by the irradiating step, wherein the temperature of the substrate is such that the vaporized particles deposited on the substrate becomes solid. The environment is sub-atmospheric pressure and the sub-atmospheric pressure is in the range of about 1×10⁻⁰ Torr to 1×10⁻⁶ Torr.

In another aspect, the present invention relates to a film made according to the above method.

In yet another aspect, the present invention relates to a method for depositing particles onto a substrate to form an N-layered structure thereon, where N is an integer greater than 1. In one embodiment, the method includes the steps of (a) providing a plurality of targets, {Tⱼ, j=1, . . . , N}, where the j-th target, Tⱼ, contains a corresponding j-th type of particles to be deposited; (b) irradiating the first target, T₁, with a light of a first wavelength in the infrared region which is resonant with a corresponding vibrational mode of the first target T₁ so as to vaporize the first type of particles in the first target T₁ without decomposing the first type of particles; (c) depositing the vaporized first type of particles onto the substrate to form a first layer thereon; and (d) repeating steps (b) and (c) for the j-th target Tⱼ to form a (j-th layer on a (j−1)-th layer, wherein j=2, 3, . . . N, so as to form a structure having N layers on the substrate, and wherein the light irradiating the j-th target Tⱼ has a j-th wavelength in the infrared region which is resonant with a corresponding vibrational mode of the j-th target Tⱼ so as to vaporize the j-th type of particles in the j-th target Tⱼ without decomposing the j-th type of particles.

In one embodiment, the providing step comprises the steps of forming N solutions, where each solution is formed with a plurality of a corresponding type of particles dispensed in a corresponding solvent or a matrix of solvents; and freezing the formed N solutions to form the N targets, respectively. In one embodiment, the forming step further comprises the step of adding a polymeric material into one or more of the N solutions.

Each of the N layers is formed of the corresponding type of particles, where each of the N types of particles is identical or substantially different from each other. In one embodiment, each of the N types of particles comprises micropartices or nanoparticles having a dimension in the range of about 1 nm to 500 μm. One or more of the N types of particles comprise functionalized particles. Each of the N solvents or matrices can be identical or substantially different from each other.

The vibrational mode of each of the N targets is selectable from an absorption spectrum of the target, and is selected such that there is substantially no electronic excitation in the target caused by irradiating the target with the light. The vibrational mode of the corresponding target is resonant with at least one vibrational mode of the corresponding solvent or matrix of solvents in a liquid form or a solid form. The vibrational mode of the corresponding target is in the infrared region of about 0.1-10,000.0 μm.

The light of a corresponding wavelength which is resonant with the vibrational mode of the corresponding target comprises a laser beam that is generated by a laser.

In a further aspect, the present invention relates to a film containing N layers of particles made according to the method disclosed above.

In yet a further aspect, the present invention relates to an apparatus for depositing particles onto a substrate, where a target is formed with the particles and a solvent or a matrix of solvents. In one embodiment, the apparatus has a light source for emitting a light of a wavelength resonant with a vibrational or electronic absorption mode of the solvent or a matrix of solvents; means for irradiating the target with the light so as to vaporize the particles in the target without decomposing the particles; and a stencil member positioned between the target and the substrate to allow the vaporized particles to pass through and form a film of particles with a pattern on the substrate, where the substrate is positioned such that the substrate and the target define a distance therebetween.

The apparatus further has a target holder for receiving the target, wherein the target holder is rotatable in operation. Additionally, the apparatus has a vacuum chamber for hosting the target and the substrate.

In one embodiment, the irradiating means comprises means for directing the light at the surface of the target along a direction, which defines an angle, α, with a normal direction of the surface of the target, and wherein the angle α is greater than 0. The irradiating means further comprises a raster positioned between the light source and the target to allow the light to be incident onto the surface of the target evenly.

The irradiating means may also have means for regulating the intensity of light so that the average fluence of the light is greater than a ablation threshold for the target.

In one embodiment, the light source includes an infrared laser. The infrared laser is capable of emitting pulses of coherent light with a fluency in a range of about 0.01 to 100 J/cm². The pulses of coherent light have a pulse duration in a range of about 100 fs to 5 ms at a pulse repetition frequency in a range of about 1 Hz to 3 GHz.

In one embodiment, the infrared laser includes a free electron laser, a CO₂ laser, a tunable optical parametric oscillator (OPO) laser system, an N₂ laser, an excimer laser, a Holmium-doped:Yttrium Aluminum Garnet (Ho:YAG) laser, or an Erbium doped: Yttrium Aluminum Garnet (“Er:YAG”) laser. In one embodiment, the infrared laser operates in a continuous wave mode.

These and other aspects of the present invention will become apparent from the following description of the preferred embodiment taken in conjunction with the following drawings, although variations and modifications therein may be affected without departing from the spirit and scope of the novel concepts of the disclosure.

### BRIEF DESCRIPTION OF THE DRAWINGS

The accompanying drawings illustrate one or more embodiments of the invention and, together with the written description, serve to explain the principles of the invention. Wherever possible, the same reference numbers are used throughout the drawings to refer to the same or like elements of an embodiment, and wherein:

FIG. 1 shows schematically an apparatus for depositing particles onto a substrate according to one embodiment of the present invention, where the frozen target containing the particles and a solvent is irradiated by a laser in a vacuum chamber, resulting in a plume of ablated material, and the solvent is pumped away and the particles collected on the substrate located several centimeters away, and the use of a stencil allows for the patterning of specific areas of the substrate;

FIG. 2 shows an SEM image of laser transferred functionalized spheres (particles) onto a substrate according to one embodiment of the present invention; and

FIG. 3 shows photoluminescence measurements of a laser transferred film of nanoparticles containing two dyes according to one embodiment of the present invention, and a film prepared by drop casting the neat suspension.

### DETAILED DESCRIPTION OF THE INVENTION

The present invention is more particularly described in the following examples that are intended as illustrative only since numerous modifications and variations therein will be apparent to those skilled in the art. Various embodiments of the invention are now described in detail. Referring to the drawings, like numbers indicate like components throughout the views. As used in the description herein and throughout the claims that follow, the meaning of “a”, “an”, and “the” includes plural reference unless the context clearly dictates otherwise. Also, as used in the description herein and throughout the claims that follow, the meaning of “in” includes “in” and “on” unless the context clearly dictates otherwise.

Additionally, some terms used in this specification are more specifically defined below, to provide additional guidance to the practitioner in describing the apparatus and methods of the invention and how to make and use them. For convenience, certain terms may be highlighted, for example using italics and/or quotation marks. The use of highlighting has no influence on the scope and meaning of a term; the scope and meaning of a term is the same, in the same context, whether or not it is highlighted. It will be appreciated that the same thing can be said in more than one way. Consequently, alternative language and synonyms may be used for any one or more of the terms discussed herein, nor is any special significance to be placed upon whether or not a term is elaborated or discussed herein. Synonyms for certain terms are provided. A recital of one or more synonyms does not exclude the use of other synonyms. The use of examples anywhere in this specification, including examples of any terms discussed herein, is illustrative only, and in no way limits the scope and meaning of the invention or of any exemplified term. Likewise, the invention is not limited to various embodiments given in this specification. Furthermore, subtitles may be used to help a reader of the specification to read through the specification, which the usage of subtitles, however, has no influence on the scope of the invention. Additionally, certain theories are proposed and disclosed herein; however, in no way they, whether they are right or wrong, should limit the scope of the invention.

As used herein, “about” or “approximately” shall generally mean within 20 percent, preferably within 10 percent, and more preferably within 5 percent of a given value or range. Numerical quantities given herein are approximate, meaning that the term “about” or “approximately” can be inferred if not expressly stated.

The present invention, among other unique features, bears in some aspects certain similarities to MALDI (matrix-assisted laser desorption/ionization) mass spectrometry and MAPLE (matrix-assisted pulsed laser evaporation), but differs primarily and fundamentally in the use of an infrared laser instead of an ultraviolet laser. In MALDI and MAPLE, ultraviolet laser light is employed to couple to electronic excitations in the irradiated material; and ultraviolet radiation is absorbed by electronic excitation. However, according to embodiments of the present invention, infrared laser irradiation is utilized to couple to materials by vibrational excitation. These different energy pathways result in significant differences in the response of organic materials. Electronic excitation results in the transformation of the material into a different final state, resulting in undesirable chemical or electronic degradation. Comparisons of the two different excitation modes of polymers have shown that resonant infrared irradiation is critical for the successful transfer of material without degradation of the material. The present invention, among other things, discloses methods and apparatus for resonant infrared laser-assisted transfer of nanoparticles, which can contain organic ligands, by utilizing a laser of a wavelength in the infrared region which is resonant with a target containing the nanoparticles. This invention distinctly differs from other infrared, laser deposition techniques such as RIR-PLD in that the transfer of particles such as functionalized particles, rather than polymers, is realized.

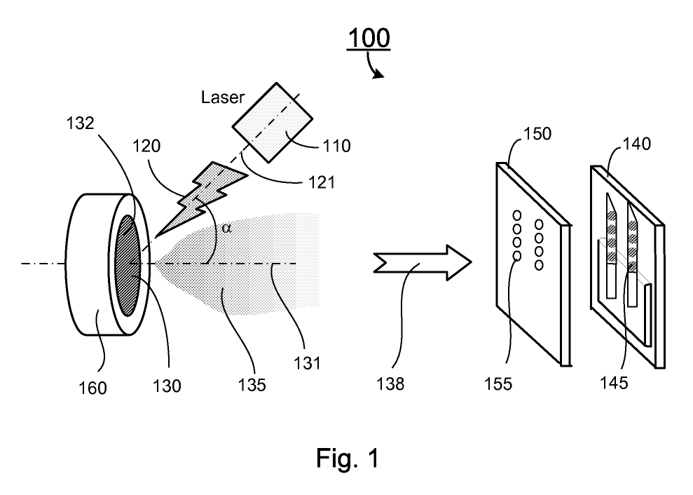

The description will be made as to the embodiments of the present invention in conjunction with the accompanying drawings of FIGS. 1-3. In accordance with the purposes of this invention, as embodied and broadly described herein, this invention, in one aspect, relates to resonant infrared laser-assisted nanoparticle transfer (RIR-LANT), a process for coating surfaces with functionalized particles ranging from a few nanometers to many micrometers in diameter. In other words, the invention in this aspect relates to a method of depositing the functionalized particles onto a substrate to form a film of the functionalized particles. The functionalized particles includes, but are not limited to, conductive particles, semiconductive particles, insulative particles, magnetic particles, therapeutic agents, or the like. The particles in size of nanometers (nanoparticles) include, but are not limited to, nanotubes, nanofibers, nanowires, quantum dots, or the like. The method makes it possible for the first time to apply uniform coatings of the functionalized particles on a wide range of material surfaces.

In one embodiment, the method for depositing particles onto a substrate includes the following steps: at first, a plurality of particles is dispensed in a solvent or a matrix of solvents to form a solution, which is frozen to form a target. The particles in the solution are in the range of about 0.1% to 40% by weight. Additionally, a polymeric material may be added into the solution. The target, which is placed in a target holder, is then irradiated with a light of a wavelength in the infrared region which is resonant with a vibrational mode of the target so as to vaporize the particles in the target without decomposing the particles. The irradiation is achieved by directing the light at the target. The target, as such formed, has a corresponding ablation threshold. When the fluence of the light is above the ablation threshold, the target, or at least part of it, will have a phase transition from a solid phase to a fluid (liquid/vapor) phase. The vaporized particles are deposited onto the substrate by a movement of the vaporized particles caused by the irradiation, at a deposition rate to form a film (layer) of particles thereon. Practically, the intensity of the light irradiating the target may be regulated or adjusted so that the average fluence of the light is greater than the ablation threshold for the target. The deposition rates of the particles vary, depending on what resonant wavelength is used. According to one embodiment of the present invention, the deposition rate of particles on the substrate is in the range of about 0.001 to 300 ng/cm²/pulse. The thickness of the film of particles deposited on the substrate is in the range of about 1 nm to 500 μm.

In operation, the target and the substrate may be subjected to an environment selected from the group consisting of sub-atmospheric, atmospheric and above atmospheric pressure, where the temperature of the substrate is such that the vaporized particles deposited on the substrate becomes solid. When the environment is sub-atmospheric pressure, the sub-atmospheric pressure is in the range of about 1×10⁻⁰ Torr to 1×10⁻⁶ Torr.

Referring to FIG. 1, an apparatus 100 for depositing particles onto a substrate is partially shown according to one embodiment of the present invention. The apparatus 100 has a target holder 160 for receiving a target 130 having a surface 132. The target 130 contains a solvent or a matrix of solvents and particles to be deposited onto a substrate 140. The substrate 140 is positioned away from the target 130 such that the target 130 and the substrate 140 define a distance therebetween, which in operation allows the ablated solvent or solvents to be moved away without reaching the substrate 140. The distance is in the range from about 1 cm to 20 cm. The apparatus 100 also has a light source 110 for emitting a light 120 of a wavelength in the infrared region, which is resonant with a vibrational absorption mode of the solvent or matrix of solvents. The emitted light 120 is directed at the surface 132 of the target 130 along a direction 121 that defines an angle, α, with a normal direction 131 of the surface 132 of the target 130, where the angle α is greater than 0, thereby irradiating the target 130 and vaporizing the solvent or solvents and the particles in the target 130. The vaporized particles move in a direction 138 towards the substrate 140 and are deposited thereon to form a film of particles.

In one embodiment, a plurality of functionalized microparticles or nanoparticles is dispensed in a solvent or a matrix of solvents to form a suspension (solution). Several milliliters of the suspension are placed into a target holder (hollowed metal disk) 160 and frozen to form the target 130. The target holder 160 receiving the target 130 is then introduced into a vacuum chamber (not shown) and positioned therein, which is subsequently brought to a low pressure vacuum. Other environments such as sub-atmospheric, atmospheric and above atmospheric pressure can also be utilized to practice the present invention. Infrared light 120 of a suitable wavelength, in the form of a laser beam from laser 110, is directed along the direction 121 into the chamber through a window (not shown) at the non-normal angle α with respect to the target surface 130. The laser spot of the laser beam is rastered on the surface 132 of the target 130, which is itself rotated by the rotation of the target holder 160 to insure that the laser spot covers the surface 132 of the target 130 as evenly as possible. The laser fluence is adjusted so that it is above the ablation threshold for the target 130, resulting in the ejection of material normal to the target surface 132 to form a plume 135 of the ablated target, which expands in motion due to the low pressure vacuum environment. During the expansion, the solvent is pumped away by the vacuum, and the vaporized (ejected) particles are collected on a substrate positioned several centimeters away. The temperature of the substrate 140 is such that the vaporized particles deposited on the substrate become solid. Additionally, a stencil 150 having a pattern 155 and positioned between the plume 135 of the ablated target and the substrate 140, can be optionally used to allow for the patterning 145 of the specific areas of the substrate 140, as shown in FIG. 1.

In the present invention, among other things, the selection of a laser wavelength is critical to producing an even coating of material and in preserving the functionality of the material. Attempts to transfer organic material with ultraviolet lasers have usually resulted in the degradation of the material due to photochemical modification. Infrared photons, being less energetic, couple instead into one or more vibrational modes of the target and at the energies used in this technique are insufficient to initiate electronic excitation. The use of infrared irradiation has the ability to transfer more material per laser shot, as the penetration depth of infrared photons is generally several orders of magnitude larger than that for ultraviolet photons for the materials of interest. Furthermore, within the infrared spectrum, there is some evidence in reports for transfer of polymeric material that selecting a mode resonant with a vibrational mode of the target is important for maintaining its physical and chemical properties. Additionally, the ablation dynamics are different at non-resonant wavelengths, and early results suggest that larger chunks of materials are generated at non-resonant wavelengths, which can result in the transfer of chunks of materials to the substrate and thus uneven coatings.

According to one embodiment of the present invention, the light using to irradiate the target has a wavelength in the infrared region which is resonant with a vibrational absorption mode of the solvent or matrix of solvents in a liquid form or a solid form. The vibrational mode of the solvent or matrix of solvents is selectable from an absorption spectrum of the target, and is selected such that there is substantially no electronic excitation in the target caused by irradiating the target with the light. In one embodiment, the vibrational mode of the target is in the infrared region of about 0.1-10,000.0 μm. Accordingly, a film of particles can be grown in minutes instead of hours or days.

In other words, the appropriate wavelength of the light, corresponding to resonant vibrational excitation, can be determined by examining the infrared absorption spectrum of the target material that is to be transferred onto a substrate in solid form via laser evaporation. The infrared spectrum has characteristic absorption bands that are used to identify the chemical structure of the material. The resonant excitation wavelength of the target can be determined by identifying the wavelength associated with one of the absorption bands, and then using a light source, such as a tunable laser in the infrared region or a fixed frequency laser that is resonant with the vibrational absorption band, to generate such light having a wavelength resonant with the vibrational absorption mode of the target, which is directed at the target material. Light of more than one resonant wavelength can also be used to practice the present invention.

The light is delivered by a light source in the form of one or more pulses or in the form of continuous waves. The one or more pulses may have the pulse duration of about 100 fs to 5 ms at a pulse repetition frequency in the range of about 1 Hz to 3 GHz.

The light source for the RIR-LANT can be a tunable laser in the infrared region or a fixed frequency laser that is resonant with the vibrational absorption band of the target according to embodiments of the present invention. The suitable laser light source in one example is an FEL that is continuously tunable in the mid-infrared range of 2-10 μm or 5,000 to 1,000 cm⁻¹. The present invention has been practiced by using an FEL at Vanderbilt University in Nashville, Tenn. The Vanderbilt FEL laser produces an approximately 4 μs wide macropulse at a repetition rate of 30 Hz. The macropulse is made up of approximately 20,000 1-ps micropulses separated by 350 ps. The energy in each macropulse is on the order of 10 mJ so that the peak unfocused power in each micropulse is very high. The average power of the FEL laser is on the order of 2-3 W. For thin films deposited on a substrate by resonant infrared pulsed laser deposition, as described herein, the fluence is typically between 2 and 3 J/cm² and typical deposition rate is 100 ng/cm²/macropulse although it is in the range of 1 to 300 ng/cm²/pulse. The picosecond pulse structure of the FEL may play a unique and critical role in making possible RIR-LANT with low pulse energy but high intensity.

Tunable, all-solid-state IR laser systems built from commercial components may also be utilized to practice the present invention. Other laser sources, for example, a CO₂ laser, a tunable optical parametric oscillator (OPO) laser system, an N₂ laser, an excimer laser, a Holmium-doped:Yttrium Aluminum Garnet (Ho:YAG) laser, or an Erbium doped: Yttrium Aluminum Garnet (“Er:YAG”) laser, or the like, can also be utilized to practice the present invention.

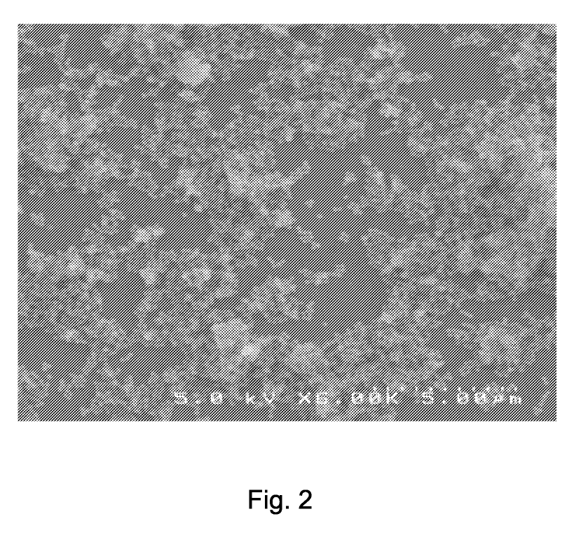

FIG. 2 shows an SEM image of the laser-transferred 2-dye nanoparticles on a silicon surface according to one embodiment of the present invention, which was conducted with 170 nm silica spheres synthesized with a dye in the core of the sphere (tetramethylrhodamine isothiocyanate, TRITC) and another dye located on the surface of the sphere (fluorescein isothiocyanate, FITC). In the exemplary example, a 1% suspension of the particles in water was frozen and irradiated with a laser tuned to a vibrational mode resonant with water. The SEM image shows that the particles form a fairly uniform coating, although some clustering was observed.

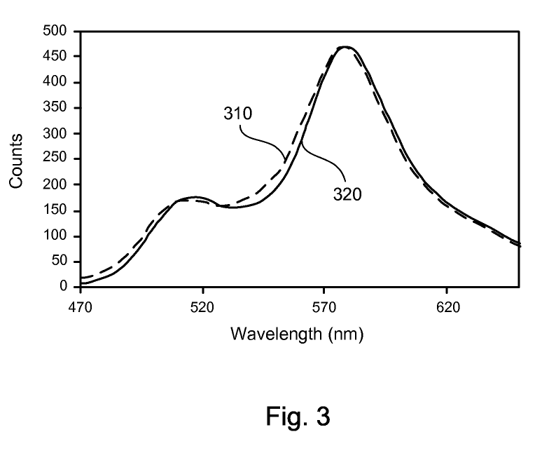

Photoluminescence measurements, as represented by curves 310 and 320, performed on these particles, FITC and TRITC, respectively, show no significant alteration of their emission properties, suggesting that no damage occurred to the encapsulated or surface-bound dye either during irradiation or during the ablation event, as shown in FIG. 3. Small changes to the peak emission wavelength or intensity ratio of the two dyes are likely due to differences in densities of the two samples, resulting in different interparticle coupling strengths. The ability to non-destructively transfer these labile and reactive ligands suggests that many more materials will be amenable to this laser transfer process. For successful applications of this invention, among other things, it would be needed to find an appropriate solvent that (1) does not unfavorably interact chemically with the functionalized particle either during or prior to transfer, (2) has a significant vapor pressure so that it easily pumped away during the ablation event, and (3) resonantly absorbs infrared irradiation.

Another aspect of the present invention relates to a method for depositing same or different types of particles onto a substrate to form a multi-layered structure thereon. Each layer is formed of a corresponding type of particles. Each type of particles can be identical or substantially different from each other. Of them, one or more type of particles include functionalized particles, such as conductive particles, semiconductive particles, insulative particles, magnetic particles, therapeutic agents, or the like, whose size can be in nanoscale or microscale.

The method in one embodiment includes the steps of (a) providing a plurality of targets, {Tⱼ, j=1, . . . , N}, wherein the j-th target, Tⱼ, contains a corresponding j-th type of particles to be deposited; (b) irradiating the first target, T₁, with a light of a first wavelength in the infrared region which is resonant with a corresponding vibrational mode of the first target T₁ so as to vaporize the first type of particles in the first target T₁ without decomposing the first type of particles; (c) depositing the vaporized first type of particles onto the substrate to form a first layer thereon; and (d) repeating steps (b) and (c) for the j-th target Tⱼ to form a j-th layer on a (j−1)-th layer, wherein j=2, 3, . . . N, so as to form a structure having N layers on the substrate. The light irradiating the j-th target Tⱼ has a j-th wavelength in the infrared region which is resonant with a corresponding vibrational mode of the j-th target Tⱼ so as to vaporize the j-th type of particles in the j-th target Tⱼ without decomposing the j-th type of particles.

The N targets are formed by freezing N solutions, respectively. Each of the N solutions contains a corresponding solvent or matrix of solvents and a corresponding type of particles dispensed in the corresponding solvent or matrix of solvents. Each of the N solvents or matrices is identical or substantially different from each other.

The present invention, among other things, may find a widespread spectrum of applications:

For example, the invented RIR-LANT can be used to coat device platforms and structures with dimensions smaller than millimeters up to sizes larger than centimeters, and to do so with a degree of spatial uniformity substantially better than many competing technologies. Potential applications also include, but are not limited to: (1) providing uniform particle coatings for a wide range of materials and functionalities; (2) increasing the effective surface area of a device by delivering a layer of nanoparticles to the surface in a controlled manner; and (3) patterning specific areas of a device without affecting other regions of the device platform. The later is a particular challenge for solvent-based techniques now used to coat surface features in the size range of about 10-100 micrometers.

The present invention provides means for increasing the surface area of a device, which should prove particularly valuable for MEMS technologies, which allows a small scale device to either increase its sensitivity or to allow for the same sensitivity on a smaller platform. The smaller platform might result in reduced material or power consumption costs. Increased surface area also benefits technologies where catalytic activity is important.

Additionally, the present invention can be combined with pulsed laser deposition of polymeric material to create either a composite or layered material. A composite coating could be created by simply transferring a composite starting material directly, similar to previous technologies referenced above, but distinct in the use of functionalized nanomaterials that would require an infrared laser as the energy source. For example, a target composed of a polymer with functionalized nanoparticles could be transferred in one step by ablating the target so that both the polymer and the nanoparticle are deposited with a controlled thickness. A composite coating could also be created by alternately exposing a target of functionalized nanomaterials in a MAPLE experiment with a second material such as a polymer. In this realization the concentration of particles in the composite material could be tailored by controlling the amount of material transferred in each step. In a similar manner, a stratified architecture could be produced consisting of alternating layers of nanoparticles with each other or another material such as a polymer. For instance, a layer of one type of nanoparticle could be deposited on a surface, overlaid with a polymeric material, and then a new type of particle could be deposited on top of it, etc. This capability would be much more difficult to obtain using solvent based techniques, since the deposition process might disturb the topmost layer by hydrodynamic motion or by dissolution of the layer beneath it.

Another application example of the present invention is the assembly of an electronic device by alternating insulating layers such as poly(tetrafluorethylene) (Teflon®) with conducting or semiconducting materials such as carbon nanotubes, which could be patterned on the underlying layer with a mask. Additionally, controlled drug delivery can be accomplished by layering a biocompatible polymer with nanoparticles tagged with ligands for specific functions. Each layer of active material could perform a different physiological function at a timed release rate.

The ability to deliver a high surface area coating to various substrates can be beneficial in improving the performance of current sensor technology for detecting both biological and chemical moieties. Uniform, solventless particle transfer onto many different kinds of substrates including glass, metals, and flexible substrates for sensor technologies, patterning technologies, and catalysis technologies can be obtained by the invented technology. It is also possible that substrates for time-release and other useful drug delivery applications could be made using this nanoparticle transfer technique.

These and other embodiments that can be developed, are based on a theory that the ablation plume as a spatially and temporally delimited reaction volume, which if properly controlled by the use of one or more components in the solvent and by the proper choice of laser vaporization protocol, can be used to produce a vapor of some desired material that is then deposited on the substrate.

The foregoing description of the exemplary embodiments of the invention has been presented only for the purposes of illustration and description and is not intended to be exhaustive or to limit the invention to the precise forms disclosed. Many modifications and variations are possible in light of the above teaching.

The embodiments were chosen and described in order to explain the principles of the invention and their practical application so as to enable others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

### LIST OF REFERENCES

[1]. “Pulsed Laser Deposition of Polymer Films Using a Resonantly Tunable Infrared Laser,” D. M. Bubb, J. H. Callahan, J. S. Horwitz, R. A. McGill, E. J. Houser, D. B. Chrisey, M. R. Papantonakis, R. F. Haglund, Jr., M. Galicia and A. Vertes, J. Vac. Sci. Tech. A 19, 2698-2702 (2001). Rapid Communication.
[2]. “Resonant Infrared Pulsed Laser Deposition of a Sorbent Chemoselective Polymer,” D. M. Bubb, D. B. Chrisey, M. R. Papantonakis, R. F. Haglund, Jr., J. S. Horwitz, R. A. McGill and B. Toftmann, Appl. Phys. Lett. 79, 2847-2849 (2001).
[3]. “Deposition of thin biodegradable polymer films by resonant infrared pulsed laser deposition,” D. M. Bubb, B. Toftmann, R. F. Haglund, Jr., Jr., J. S. Horwitz, M. R. Papantonakis, R. A. McGill, P. W. Wu, and D. B. Chrisey, Applied Physics A 121, 123-125 (2002).
[4]. “Vapor Deposition of Polystyrene Thin Films by Intense Laser Excitation of Resonant Vibrational Modes,” D. M. Bubb, M. R. Papantonakis, R. F. Haglund, Jr., J. S. Horwitz, R. A. McGill and D. B. Chrisey, Chemical Physics Letters 352, 135-139 (2002)
[5]. “Effect of ablation parameters on infrared pulsed laser deposition of poly(ethylene glycol) thin films,” D. M. Bubb, M. R. Papantonakis, B. Toftmann, J. S. Horwitz, E. J. Houser, D. B. Chrisey and R. F. Haglund, Jr., Journal of Applied Physics 91, 9809-9814 (2002).
[6]. “Laser deposition of polymer and biomaterial films”, D. B. Chrisey, A. Pique, R. A. McGill, J. S. Horwitz, B. R. Ringeisen. D. M. Bubb and P. K. Wu, Chemical Reviews, 103, 553-576 (2003).
[7]. “UV and RIR matrix-assisted pulsed laser deposition of MEH-PPV films,” B. Toftmann, M. R. Papantonakis, R. C. Y. Auyeung, W. Kim, S. M. O'Malley, D. M. Bubb, J. S. Horwitz, J. Schou, P. M. Johansen and R. F. Haglund, Jr., Thin Solid Films 453-454, 177-181 (2004).

[8]. “Pulsed Laser Deposition of Polymers at High Vibrational Excitation Density: the Case of Poly(tetrafluoroethylene),” M. R. Papantonakis and R. F. Haglund, Jr., Applied Physics A: Materials and Processing 79, 1687-1694 (2004).
[9]. “Applications of Free-Electron Lasers in the Biological and Materials Sciences,” G. S. Edwards, S. J. Allen, R. F. Haglund, Jr., R. J. Nemanich, B. Redlich, J. D. Simon and W. C. Yang, Photochemistry and Photobiology 81, 711-735 (2005). Invited review.

[10]. “Mode-specific effects in resonant ablation and deposition of polystyrene,” D. M. Bubb, S. L. Johnson, Jr., R. J. Belmont, K. E. Schriver, R. F. Haglund, Jr., C. Antonacci and L. S. Yeung, Applied Physics A: Materials and Processing 83, 147-151 (2006).
[11]. “Resonant infrared pulsed laser deposition of a polyimide precursor,” N. L. Dygert, K. E. Schriver and R. F. Haglund, Jr., in press, Institute of Physics Conference Series, proceedings of the Eighth International Conference on Laser Ablation (2005).

What is claimed is:

1. A method for depositing particles onto a substrate, comprising the steps of:
a. providing a plurality of particles in a solvent or a matrix of solvents to form a solution;
b. freezing the solution to form a target having a surface;
c. irradiating the target with a light of a wavelength in the infrared region which is resonant with a vibrational mode of the target so as to vaporize the particles in the target without decomposing the particles; and
d. depositing the vaporized particles onto the substrate at a deposition rate to form a film of particles thereon,
wherein the substrate is positioned such that the substrate and the target define a distance therebetween.

2. The method of claim 1, wherein the irradiating step comprises the step of directing the light at the surface of the target along a direction, which defines an angle α with a normal direction of the surface of the target, and wherein the angle α is greater than 0.

3. The method of claim 2, wherein the irradiating step further comprises the step of rastering the light onto the surface of the target.

4. The method of claim 3, wherein the target is positioned in a target holder that is rotated during the rastering step to allow the light to evenly cover the surface of the target.

5. The method of claim 1, wherein the irradiating step comprises the step of regulating the intensity of the light so that the average fluence of the light is between a first value and a second value that is greater than the first value.

6. The method of claim 5, wherein the first value is corresponding to the ablation threshold for the target.

7. The method of claim 1, wherein the vibrational mode of the target is selectable from an absorption spectrum of the target, and is selected such that there is substantially no electronic excitation in the target caused by irradiating the target with the light.

8. The method of claim 7, wherein the vibrational mode of the target is resonant with at least one vibrational mode of the solvent or matrix of solvents in a liquid form or a solid form.

9. The method of claim 7, wherein the vibrational mode of the target is in the infrared region of about 0.1-10,000.0 μm.

10. The method of claim 1, wherein the light of a wavelength in the infrared region which is resonant with a vibrational mode of the target comprises a laser beam that is generated by a laser.

11. The method of claim 10, wherein the laser comprises a tunable laser.

12. The method of claim 10, wherein the laser operates in a continuous wave mode.

13. The method of claim 10, wherein the laser beam is provided in the form of one or more pulses having a pulse duration of about 100 fs to 5 ms at a pulse repetition frequency in the range of about 1 Hz to 3 GHz.

14. The method of claim 13, wherein the deposition rate of particles on the substrate is in the range of about 0.001 to 300 ng/cm²/pulse.

15. The method of claim 1, further comprising the steps of subjecting the target and the substrate to an environment selected from the group consisting of sub-atmospheric, atmospheric and above atmospheric pressure and locating the target and the substrate in the vicinity of each other so that the vaporized particles from the target can be deposited on the substrate by a movement of the vaporized particles caused by the irradiating step, wherein the temperature of the substrate is such that the vaporized particles deposited on the substrate becomes solid.

16. The method of claim 15, wherein the environment is sub-atmospheric pressure and the sub-atmospheric pressure is in the range of about 1×10⁻⁰ Torr to 1×10⁻⁶ Torr.

17. The method of claim 16, wherein the distance between the target and the substrate is in the range of about 1 to 20 cm, which allows the ablated solvent or solvents to be moved away without reaching the substrate.

18. The method of claim 1, wherein the thickness of the film of particles deposited on the substrate is in the range of about 1 nm to 500 μm.

19. The method of claim 18, wherein the film is formed in a pattern.

20. The method of claim 1, wherein the solvent or matrix of solvents comprises water.

21. The method of claim 1, wherein the particles in the solution is in the range of about 0.1% to 40% by weight.

22. The method of claim 1, wherein the plurality of particles comprises micropartices or nanoparticles having a dimension in the range of about 1 nm to 500 μm.

23. The method of claim 22, wherein the nanoparticles comprise nanotubes, nanofibers, nanowires, quantum dots, or any combinations of them.

24. The method of claim 1, wherein the plurality of particles comprises functionalized particles.

25. The method of claim 24, wherein the functionalized particles comprise conductive particles, semiconductive particles, insulative particles, magnetic particles, or combinations of them.

26. The method of claim 24, wherein the functionalized particles comprise therapeutic agents.

27. The method of claim 24, wherein the functionalized particles comprise one or more organic ligands.

28. The method of claim 1, wherein the providing step further comprises the step of adding a polymeric material into the solution.

29. A film made according to the method of claim 1.

30. A method for depositing particles onto a substrate to form an N-layered structure thereon, wherein N is an integer greater than 1, comprising the steps of:
a. providing a plurality of targets, {Tⱼ, j=1, . . . , N}, wherein the j-th target, Tⱼ, contains a corresponding j-th type of particles to be deposited;
b. irradiating the first target, T₁, with a light of a first wavelength in the infrared region which is resonant with a corresponding vibrational mode of the first target T₁ so as to vaporize the first type of particles in the first target T₁ without decomposing the first type of particles;
c. depositing the vaporized first type of particles onto the substrate to form a first layer thereon; and
d. repeating steps (b) and (c) for the j-th target Tⱼ to form a j-th layer on (j−1)-th layer, wherein j=2, 3, . . . N, so as to form a structure having N layers on the substrate, and wherein the light irradiating the j-th target T has a j-th wavelength in the infrared region which is resonant with a corresponding vibrational mode of the j-th target Tⱼ so as to vaporize the j-th type of particles in the j-th target Tⱼ without decomposing the j-th type of particles.

31. The method of claim 30, wherein the providing step comprises the steps of:
a. forming N solutions, wherein each solution is formed with a plurality of a corresponding type of particles dispensed in a corresponding solvent or a matrix of solvents; and
b. freezing the formed N solutions to form the N targets, respectively.

32. The method of claim 31, wherein each of the N layers is formed of the corresponding type of particles.

33. The method of claim 32, wherein each of the N types of particles is identical or substantially different from each other.

34. The method of claim 33, wherein each of the N types of particles comprises micropartices or nanoparticles having a dimension in the range of about 1 nm to 500 μm.

35. The method of claim 33, wherein one or more of the N types of particles comprise functionalized particles.

36. The method of claim 31, wherein the forming step further comprises the step of adding a polymeric material into one or more of the N solutions.

37. The method of claim 31, wherein each of the N solvents or matrices is identical or substantially different from each other.

38. The method of claim 30, wherein the vibrational mode of each of the N targets is selectable from an absorption spectrum of the target, and is selected such that there is substantially no electronic excitation in the target caused by irradiating the target with the light.

39. The method of claim 38, wherein the vibrational mode of the corresponding target is resonant with at least one vibrational mode of the corresponding solvent or matrix of solvents in a liquid form or a solid form.

40. The method of claim 38, wherein the vibrational mode of the corresponding target is in the infrared region of about 0.1-10,000.0 μm.

41. The method of claim 40, wherein the light of a corresponding wavelength which is resonant with the vibrational mode of the corresponding target comprises a laser beam that is generated by a laser.

42. A film containing N layers of particles made according to the method of claim 30.

43. An apparatus for depositing particles onto a substrate, wherein a target is formed with the particles and a solvent or a matrix of solvents, comprising:
a. a light source for emitting a light of a wavelength resonant with a vibrational or electronic absorption mode of the solvent or a matrix of solvents;
b. means for irradiating the target with the light so as to vaporize the particles in the target without decomposing the particles; and
c. a stencil member positioned between the target and the substrate to allow the vaporized particles to pass through and form a film of particles with a pattern on the substrate,
wherein the substrate is positioned such that the substrate and the target define a distance therebetween.

44. The apparatus of claim 54, wherein the irradiating means comprises means for directing the light at the surface of the target along a direction, which defines an angle α with a normal direction of the surface of the target, and wherein the angle α is greater than 0.

45. The apparatus of claim 44, wherein the irradiating means further comprises a raster positioned between the light source and the target to allow the light to be incident onto the surface of the target evenly.

46. The apparatus of claim 45, wherein the irradiating means comprises means for regulating the light so that the average fluence of the light is greater than a ablation threshold for the target.

47. The apparatus of claim 43, further comprising a target holder for receiving the target, wherein the target holder is rotatable in operation.

48. The apparatus of claim 43, further comprising a vacuum chamber for hosting the target and the substrate.

49. The apparatus of claim 43, wherein the light source comprises an infrared laser.

50. The apparatus of claim 49, wherein the infrared laser is capable of emitting pulses of coherent light with a fluency in a range of about 0.01 to 100 J/cm².

51. The apparatus of claim 50, wherein the pulses of coherent light have a pulse duration in a range of about 100 fs to 5 ms at a pulse repetition frequency in a range of about 1 Hz to 3 GHz.

52. The apparatus of claim 51, where the infrared laser operates in a continuous wave mode.

53. The apparatus of claim 49, where the infrared laser comprises a free electron laser, a CO₂ laser, a tunable optical parametric oscillator (OPO) laser system, an N₂ laser, an excimer laser, a Holmium-doped:Yttrium Aluminum Garnet (Ho:YAG) laser, or an Erbium doped: Yttrium Aluminum Garnet (“Er:YAG”) laser.
